(19) United States
(12) Patent Application Publication
(10) Pub. No.: US 2014/0030628 A1
(43) Pub. Date: Jan. 30, 2014

(54) PHOTOCATALYTIC FUEL CELL AND ELECTRODE THEREOF

(71) Applicant: Fordham University, Bronx, NY (US)

(72) Inventor: John J. McMahon, Yonkers, NY (US)

(73) Assignee: FORDHAM UNIVERSITY, Bronx, NY (US)

(21) Appl. No.: 13/950,424

(22) Filed: Jul. 25, 2013

Related U.S. Application Data
(60) Provisional application No. 61/676,018, filed on Jul. 26, 2012.

(51) Int. Cl. H01M 4/86; H01L 29/40

(52) U.S. Cl. CPC H01M 4/8657; H01L 29/401
USPC 429/482; 438/652

(57) ABSTRACT

The invention provides a novel fuel cell, the output voltage of which is pH dependent. The fuel cell comprises a membrane electrode assembly and a light source. In accordance with one embodiment, the membrane electrode assembly includes i) an electrolyte; ii) an anode operably coupled to the electrolyte; and iii) a cathode operably coupled to the electrolyte, wherein the cathode is made from an electrically conductive material and has an unroughened surface where an adsorbate material is applied. The adsorbate material used herein comprises a material having semiconductor properties, and the combination of the electrically conductive material and the adsorbate material is photosensitive and has catalytic properties. The invention also provides a novel electrode that can be used as a cathode in a fuel cell, a novel method for making the electrode, and a novel method of generating electricity using the fuel cell and/or electrode of the invention.

### CROSS REFERENCE RELATED APPLICATION

This application claims under 35 U.S.C. §120 and §119(e) the benefit of U.S. Provisional Patent Application No. 61/676,018 filed Jul. 26, 2012, the entire contents of which are incorporated herein by reference.

### FIELD OF THE INVENTION

The present invention relates to a fuel cell and a method for producing the fuel cell, the output voltage of which is pH dependent. Particularly, the present invention is directed to a fuel cell comprising a membrane electrode assembly which includes an electrolyte; an anode and a cathode coupled to the electrolyte, and a light source.

### BACKGROUND OF THE INVENTION

A variety of fuel cell devices are known in the art for generating electric power. Of such devices, most include graphite anodes and cathodes comprising a finely dispersed platinum catalyst.

For example, a phosphoric acid fuel cell (PAFC) is a power generation cell which employs a porous electrolyte layer of silicon carbide matrix for retaining concentrated phosphoric acid. The electrolyte layer is interposed between carbon-based electrodes (an anode and a cathode) to form an electrolyte electrode assembly, sometimes referred to as a membrane electrode assembly (“MEA”). The membrane electrode assembly is then interposed between electrically conductive bipolar plates. The membrane electrode assembly and the bipolar plates form a single fuel cell for generating electricity by reacting a fuel such as hydrogen with oxygen across the electrolyte. A single fuel cell as described generally herein has an output voltage of about 0.8 volts. To raise the voltage of the electrical output, a fuel cell stack can be formed by arranging any desired number of fuel cells in electrical series on top of one another. Since the bipolar plates are electrically conductive, current flows through the stack via the end plates.

Another type of fuel cell device is a solid polymer electrolyte fuel cell which employs a membrane electrode assembly including electrodes separated by a polymer ion exchange membrane (proton exchange membrane or PEM). Similarly, the membrane electrode assembly and the bipolar plates make up a unit of the power generation cell. Once again, a predetermined number of the power generation cells can be stacked together to form a fuel cell stack having a desired output voltage.

In the fuel cell stacks, a fuel gas such as a hydrogen-containing gas is supplied to the anode. The anode includes a catalyst that induces a chemical reaction of the fuel gas to split the hydrogen molecule into hydrogen ions (protons) and electrons. The hydrogen ions move toward the cathode through the electrolyte, and the electrons flow through an external circuit to the cathode, creating a DC electric current.

The fuel cell should be operated at or near an optimum temperature for the performance of power generation. Generally, fuel cells known in the art operate at temperatures significantly above ambient or room temperature (e.g., 75° F.). The optimum temperature for operation can vary with each type of fuel cell system. For example, a phosphoric acid fuel cell is operated in the temperature range of 120° C. to 200° C., and a solid polymer electrolyte fuel cell is operated in the temperature range of 60° C. to 90° C. In order to maintain the temperature of the power generation cells in the desirable temperature range, various cooling systems have been adopted. Typically, the power generation cells are cooled by supplying coolant such as water to a coolant passage formed in the bipolar plates of the fuel cell stack.

Generally, fuel cells provide an environmentally clean alternative to energy production from fossil fuel combustion. The electrochemical efficiency of a fuel cell (currently ≈65%) handily exceeds that of internal combustion engines (<30%). However, in spite of recent increases in the prices of crude oil and natural gas, fossil fuel combustion continues to hold a significant economic advantage over fuel cells. The high cost of fuel cell energy production is attributable to the need for addition of expensive catalysts (platinum) to accelerate the oxidation of the fuel (hydrogen) at the anode and the reduction of oxygen at the cathode. The slow oxygen reduction reaction alone accounts for the largest limitation to the fuel cell efficiency, even in the presence of platinum catalyst.

The demand by dioxygen molecules (O₂) for electrons during reduction at electropositive metal electrodes forces the electrostatic potential of the metal to wander negatively (referred to as a large negative overvoltage) before giving up the electrons needed by oxygen. Because the output power of a fuel cell is defined by the product of the cell potential (V) and current (I), i.e., P=VI, a drop in the potential lowers the power output and the cell efficiency linearly. Typically, a platinum-catalyzed hydrogen fuel cell operates at moderate current levels at cell voltages close to +0.75 volts instead of the thermodynamic equilibrium cell voltage of +1.23 volts. This amounts to an overvoltage of −0.48 volts below the thermodynamic voltage, thus limiting the efficiency to near 60%. Experiments probing alternatives to platinum catalysis of the electroreduction of oxygen continue to define a vigorous area of research. Nonetheless, platinum remains the best known electrocatalyst of the oxygen reduction reaction. In recent years, advances in fuel cell utility have relied upon improved methods for dispersing the platinum catalyst only at the active sites of graphite electrodes. The total amount of platinum needed to sustain operational currents was thereby reduced, along with the overall cost of fuel cells. However, the fundamental limitation caused by the overvoltage problem still persists.

Thus, there remains a compelling need in the art for a fuel cell that is more electrochemically efficient than known fuel cells. There is also a continuing need for a fuel cell system that can be operated economically at lower temperatures, such as at room temperature. The present invention provides a solution for these problems.

### SUMMARY OF THE INVENTION

The purpose and advantages of the present invention will be set forth in and become apparent from the description that follows, as well as will be learned by practice of the invention. Additional advantages of the invention will be realized and attained by the methods and systems particularly pointed out in the written description and claims hereof, as well as from the appended drawings.

To achieve these and other advantages and in accordance with the purpose of the invention, as embodied herein and broadly described, the invention includes a fuel cell, which comprises a membrane electrode assembly and a light source. The membrane electrode assembly includes i) an electrolyte; ii) an anode operably coupled to the electrolyte; and iii) a cathode operably coupled to the electrolyte, wherein the cathode is made from an electrically conductive material, the cathode has a surface applied with an adsorbate material, and the adsorbate material comprises a material having semiconductor properties; wherein said surface of the cathode is unroughened (or not yet subject to a pre-roughening process), and said electrically conductive material and/or the adsorbate material are photosensitive and have catalytic properties.

The light source used herein is adapted and configured to irradiate the cathode to cause a steady flow of electrical current at the cathode.

In accordance with certain embodiments of the invention, the output voltage of the fuel cell is pH dependent. In a specific embodiment, the cathode is a silver/silver iodide cathode.

The invention also provides a method of making an electrode with an adsorbate material applied to a surface thereto. In particular, the method of the invention comprises the following steps:

a) providing an electrode made from an electrically conductive material;

b) polishing said electrode; and

c) applying the adsorbate material to the surface of the electrode, wherein said adsorbate material comprises a material having semiconductor properties, and said electrically conductive material and/or the adsorbate material are photosensitive and have catalytic properties;

and said electrode is not subjected to a roughening process of the surface thereof.

Other aspects of the invention include a method of producing electricity through a pH-dependent fuel cell. For example, the method comprises

a) providing a cathode made from an electrically conductive material, wherein said cathode has a surface applied with an adsorbate material, said adsorbate material comprises a material having semiconductor properties, and said electrically conductive material and/or the adsorbate material are photosensitive and have catalytic properties;

b) operably coupling the cathode to a first portion of an electrolyte in the fuel cell;

c) operably coupling an anode to a second portion of the electrolyte; and

d) irradiating the cathode to cause an electrical current to flow across the cathode.

In an embodiment, the surface of the cathode is unroughened. In another embodiment, the method further comprises a step of adjusting the pH value of the electrolyte.

It is to be understood that both the foregoing general description and the following detailed description are exemplary and are intended to provide further explanation of the invention claimed.

The accompanying drawings, which are incorporated in and constitute part of this specification, are included to illustrate and provide a further understanding of the method and system of the invention. Together with the description, the drawings serve to explain the principles of the invention.

### BRIEF DESCRIPTION OF THE DRAWINGS

FIG. 1 depicts the electroreduction of gold (-), silver (□), and platinum (◯) in aqueous 0.01 M HClO₄.

FIG. 2 is a Pourbaix diagram showing the pH dependence of each half-cell reaction in the traditional and photocatalytic fuel cells.

FIG. 3 is a surface Raman spectrum of AgI film at a silver electrode showing an I₂-like vibrational line at 119 cm⁻¹.

FIG. 4 is a diagram showing measured and calculated cell voltages as a function of pH for the Ag/AgI photocatalytic fuel cell.

FIG. 5 is a diagram showing polarization curves in aqueous fuel cells: a fuel cell with a platinum cathode is compared with the Ag/AgI photocathode in the dark at pH 2.0 and under irradiation at pH 2.0♦ and 8.0▪.

FIG. 6 depicts a prototype of a PEM fuel cell with a photocatalytic silver cathode.

FIG. 7 shows a silver surface polished with Al₂O₃ powder.

### DETAILED DESCRIPTION OF THE INVENTION

The present invention provides a fuel cell, which comprises a membrane electrode assembly and a light source. The membrane electrode assembly includes i) an electrolyte; ii) an anode operably coupled to the electrolyte; and iii) a cathode operably coupled to the electrolyte, wherein the cathode is made from an electrically conductive material, the cathode has a surface where an adsorbate material is applied, and the adsorbate material comprises a material having semiconductor properties. In certain embodiments, the surface of the cathode is not pre-roughened (in other words, unroughened), and the combination of the electrically conductive material and the adsorbate material is photosensitive and has catalytic properties. The light source is adapted and configured to irradiate the cathode to cause a steady flow of electrical current at the cathode.

In certain embodiments, the output voltage of the fuel cell is pH dependent.

The invention also provides a method of making an electrode of the invention, and a method of producing electricity through a pH-dependent fuel cell.

Reference will now be made in detail to embodiments provided infra., and examples of which are illustrated in the accompanying drawings. The method and corresponding steps of the invention are described in conjunction with the detailed description of the system.

### Fuel Cells

One aspect of the invention provides a novel fuel cell, which produces pH-dependent cell voltage (E_{cell}). In certain embodiments, the invention provides a fuel cell comprising a membrane electrode assembly and a light source, wherein the membrane electrode assembly comprises i) an electrolyte; ii) an anode operably coupled to the electrolyte; and

iii) a cathode that is operably coupled to the electrolyte (as delineated in detail herein).

In conventional fuel cells, the demand by dioxygen molecules (O₂) for electrons during reduction at electropositive metal electrodes forces the electrostatic potential of the metal to wander negatively (referred to herein as a large negative overvoltage) before giving up the electrons to oxygen.

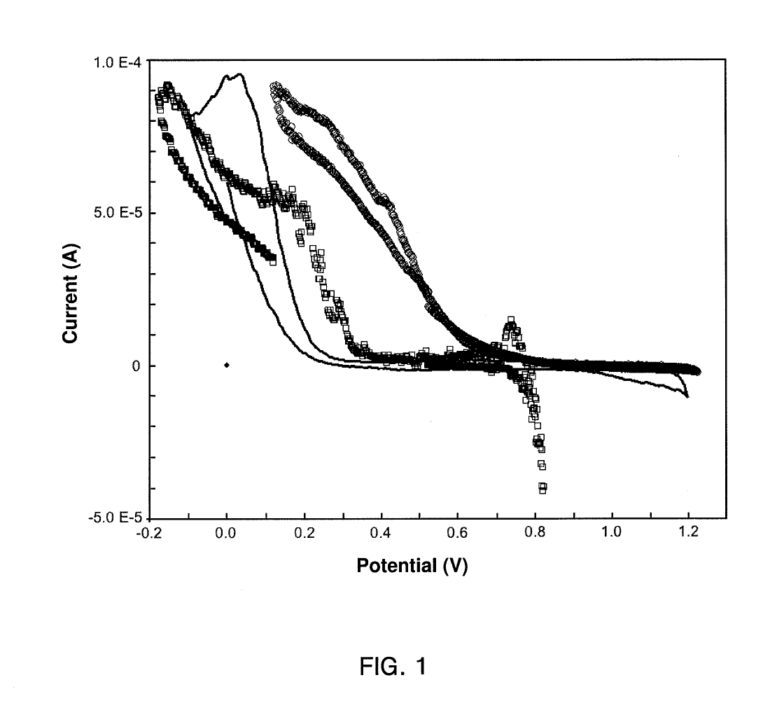

FIG. 1 compares the reduction of oxygen at silver and platinum electrodes without benefit of the invention described herein. These results are provided to demonstrate the relative catalytic behavior of platinum compared to silver prior to the application of the photocatalysis described herein. In FIG. 1, the electrode area is 0.15 Cm²

As illustrated in FIG. 1, silver does not appear as attractive as platinum for use in a fuel cell cathode. Specifically, when compared to the thermodynamic voltage for oxygen reduction of 1.23 volts vs. a Normal Hydrogen Electrode (“NHE”, described below), oxygen reduction at platinum commences near +0.75 volts, at silver near +0.35 volts. and at gold near +0.25 volts. Equivalent current densities for oxygen reduction at gold, silver, and platinum are observed when platinum is polarized near +0.25 volts more anodic than silver, and 0.35 volts more anodic than gold, highlighting the catalytic performance of platinum, though nonetheless still requiring at least a half-volt overvoltage below the thermodynamic voltage.

Furthermore, as shown in FIG. 1, silver begins to oxidize in the perchloric acid medium near +0.80 volts while platinum and gold begin to oxidize near +1.1 volts. Thus, even with complete removal of the overvoltage for oxygen reduction at silver, silver is limited by its own oxidation to commence reduction of oxygen at voltages no more positive than +0.80 volts, i.e., effectively matching the utility of platinum.

Nevertheless, due to the reason that the cost of silver is less than 1/100^{th} that of platinum, silver is still commercially attractive to be used as a replacement for platinum in fuel cell energy production.

In the field, efforts have been made to construct fuel cells that largely reduce the requirement for the overvoltage in the reduction of oxygen. This permits operating a device such as a fuel cell near or at the thermodynamic equilibrium cell voltage of +1.23 volts, limited only by the oxidation potential of the particular metal used for the cathode. This makes the use of silver and other particular metals as cathodes very attractive.

Further, as well understood in the art, voltage of a fuel cell is determined by a difference in the thermodynamic equilibrium established at the cathode and the anode. In a typical fuel cell comprised of dispersed platinum on carbon electrodes at both the cathode and anode the thermodynamic equilibria that control the cell voltage are:

at the cathode: O₂(g)+4H⁺(aq)+4e−(aq)<=>2H₂O(l)^{E°}O₂/H₂O=1.229 volts

at the anode: 4H⁺(aq)+4e−(aq)<=>2H₂(g)^{E°}H₂/H⁺=0.000 volts

Accordingly, at open circuit, when no current flows, the voltage of each half-cell is governed by the Nernst equation as follows:

At the cathode:

$${E}_{R} ( volts ) = {E}_{{O}_{2} / {H}_{2} O}^{0} - \frac{RT}{4 F} ln [ \frac{1}{{p}_{{O}_{2}} {a}_{{H}^{+}}^{4}} ] = 1.229 - 0.0591 pH$$

At the anode:

$${E}_{L} ( volts ) = {E}_{{H}_{2} / {H}^{+}}^{0} - \frac{RT}{4 F} ln [ \frac{{p}_{{H}_{2}}}{{a}_{{H}^{+}}^{4}} ] = 0.00 - 0.0591 pH$$

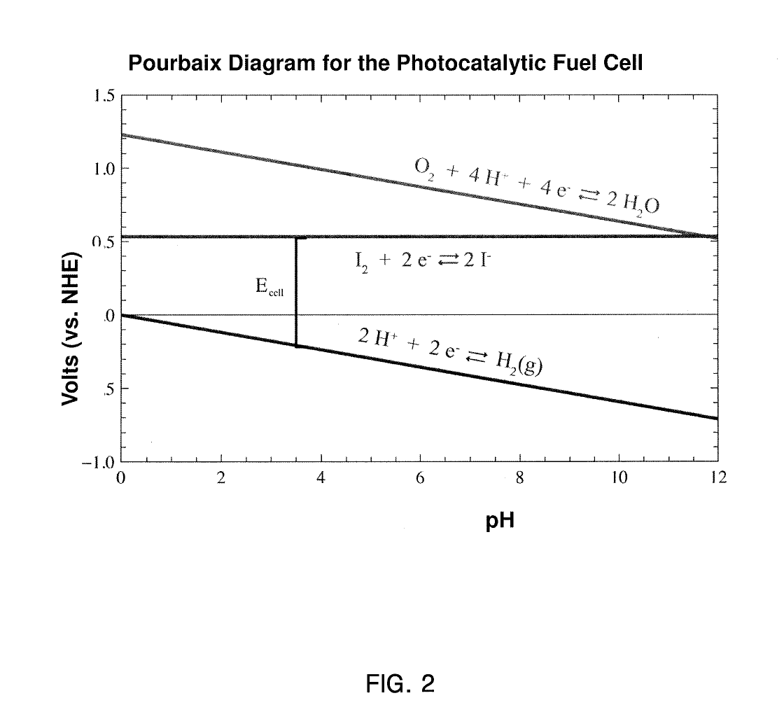

Thus, the open-circuit voltage of a traditional fuel cell is constant over all pH values (the top line minus the bottom line in FIG. 2).

E_{cell}=E_{R}−E_{L}=1.229 volts−0.0591 pH−0.00 volts+0.0591 pH=1.229 volts

By contrast, the present invention provides a fuel cell, the cell voltage (E_{cell}) of which is pH-dependent. In certain embodiments, the fuel cell in accordance with the invention comprises a membrane electrode assembly and a light source, with the membrane electrode assembly including

i) an electrolyte;

ii) an anode operably coupled to the electrolyte; and

iii) a cathode operably coupled to the electrolyte, wherein the cathode is made from an electrically conductive material, the cathode has a surface where an adsorbate material is applied, and the adsorbate material comprises a material having semiconductor properties, wherein the surface of the cathode in accordance with the invention is unroughened, and the combination of the electrically conductive material and the adsorbate material is photosensitive and has catalytic properties;

wherein the light source is adapted and configured to irradiate the cathode to cause a steady flow of electrical current at the cathode.

In one embodiment, the invention provides a hydrogen fuel cell, such as, an aqueous fuel cell. In another embodiment, the invention provides a gas phase fuel cell.

In a specific embodiment, the cathode used herein is a silver/silver iodide electrode (discussed in detail below).

It is believed that the anode in the fuel cell in accordance with the present invention could be any type of anode that has been used in a conventional fuel cell. Anodes that are conventionally used in a fuel cell include, but are not limited to, platinum anodes, platinized metal anodes, electro plating anodes, and the like. Specific examples of the anodes are, for example, platinized titanium plate anode, platinised titanium mesh anode, titanium anode with platinum catalyst, platinized titanium perforated plate anode, platinized titanium anode, platinized niobium anode, platinised zirconium anode, platinised tantalum anode, electrowinning anode, automobile parts plating anode, copper foil plating anode, hard chrome plating anode, potogravure cylinder plating anode, metal oxide coated anodes, platinized niobium box anode, platinised tantalum rod anode, platinized titanium wire anode, platinized zirconium ring anode, platinized niobium plate anode, and the like.

In certain circumstances, the anode used herein is a traditional Pt/C electrode (or an electrode having dispersed Pt on carbon). As the hydrogen overvoltage is small compared to the oxygen overvoltage, it is believed that the anode would not be a large factor in determining the efficiency of the fuel cell in accordance of the invention.

Fuel cells of the invention can come in a variety of sizes and shapes. Further, the fuel cells of the invention can be “stacked”. Such as, a plurality of fuel cells are arranged to form a stack. Each fuel cell can include a cathode, an anode and an electrolyte. Alternatively, a plurality of horizontal units can be arranged into a stack to obtain a higher output voltage.

Types of fuel cells known in the art include, but are not limited to, metal hydride fuel cell, electro-galvanic fuel cell, direct formic acid fuel cell (DFAFC), zinc-air battery, microbial fuel cell, upflow microbial fuel cell (UMFC), regenerative fuel cell, direct borohydride fuel cell, alkaline fuel cell, direct methanol fuel cell, reformed methanol fuel cell, direct-ethanol fuel cell, proton exchange membrane (PEM) fuel cell, phosphoric acid fuel cell, molten carbonate fuel cell, tubular solid oxide fuel cell (TSOFC), protonic ceramic fuel cell, direct carbon fuel cell, solid oxide fuel cell, enzymatic biofuel cells, and magnesium-air fuel cell.

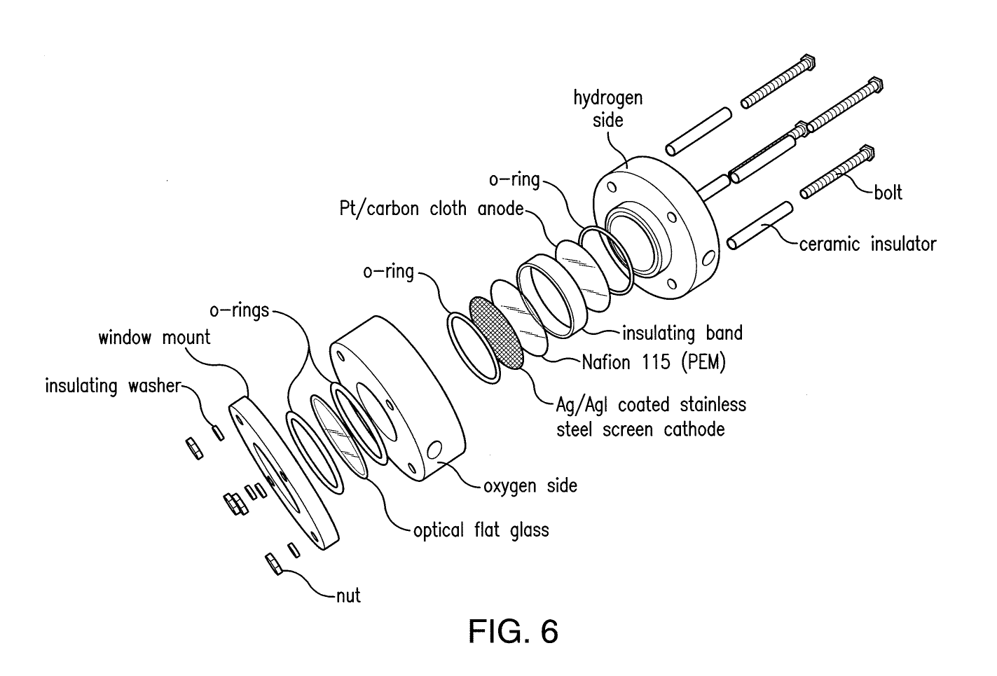

It is believed that the fuel cell in accordance with this invention can be any of the above delineated types. By way of illustration, FIG. 6 presents a prototype of a PEM fuel cell of the invention with a photocatalytic silver cathode.

For purposes of illustration and not limitation, embodiments of a fuel cell structure are described herein in detail. Fuel cells as described herein bear a number of similarities to those known in the art, however, there are certain unique differences.

Contemporary fuel cells hide the cathode below a graphite gas distribution layer, a layer that serves as the cathode terminal while uniformly distributing oxygen to the entire surface of the cathode and managing removal of water generated in the reaction. On the other hand, a fuel cell of the invention requires irradiation of the cathode to operate. Since the cathode must be irradiated, the gas distribution layer common to fuel cells known in the art must be modified or removed in favor of access of light to the cathode such as via an optical flat glass or other transparent or light conducting material.

Further, modern fuel cells make use of porous graphite paper (or cloth) that supports the dispersed platinum catalyst. The porous graphite serves as the throttle necessary to maintain a liquid/gas interface between an electrolyte, such as a proton exchange membrane (PEM) solid electrolyte layer, and the oxygen gas. Diffusion of protons through the graphite pores of the anode, into the PEM layer, and across to the cathode completes the circuit. The cathode of a fuel cell described herein differs from those known in the art by being made from a conductive material including an adsorbate material applied thereto as described above. In accordance with one embodiment, a porous photocatalytic material such as silver is employed that doubles as a gas distribution layer and cathode terminal.

While conventional PEM (proton exchange membrane) fuel cells operate near 80° C. to accelerate the reaction kinetics, a photocatalytic fuel cell made in accordance with the teachings herein can operate optimally at ambient temperature (e.g., 75° F.).

Silver can be manufactured to form porous screens. For example, stainless steel screens of varying mesh sizes including 400×400 wires per inch can be easily electroplated with silver or other metal to provide a porous conductive electrode. After application of an appropriate adsorbate film, these screens can serve as the catalyst (when irradiated) for electroreduction of oxygen and as a porous support of the oxygen-PEM interface. Pores of diameter greater than the wavelength of light used to irradiate the cathode can serve as light pipes deep into the porous silver and increasing the active surface area. There is no need for a gas distribution layer since the porous silver layer is a metal that easily serves as the cathode terminal.

In one embodiment, a fuel cell of the invention is constructed with silver screens. In another embodiment, covalently synthesized silver membranes (such as, those manufactured by Sterlitech Corporation, Kent, Wash.) may also be used. In these circumstances, due to the finding that some Sterlitech membranes were poorly porous toward oxygen and nearly opaque to light, it is thus believed that silver screens offer certain advantages over Sterlitech membranes in constructing a fuel cell in accordance with the invention.

An exemplary embodiment of a prototype of a PEM fuel cell made in accordance with the invention is depicted in FIG. 6. As depicted, the fuel cell includes a Pt/carbon anode, a Ag/AgI coated stainless steel screen cathode, NAFION™ 115 (PEM), a hydrogen side, bolts, ceramic insulators, an insulating band. An optical flat glass is also provided, which permits irradiation of the cathode with a variety of light sources to initiate photocatalysis. A plurality of o-rings are provided for sealing. A window mount is also provided into which the fuel cell is mounted.

A 10% Pt/carbon catalyst applied to the anode can serve as a traditional catalyst for the hydrogen oxidation side of the cell. In accordance with one embodiment, the 10% Pt/carbon catalyst can be painted on one side of a carbon cloth and the painted carbon cloth is then disposed on top of the PEM with the painted side of the cloth facing the PEM. The opposite side of the PEM layer is then painted with a thin film of DuPont™ NAFION® PFSA (perfluorosulfonic acid/PTFE copolymer) (also available from DuPont Fuel Cells, Fayetteville, N.C., U.S.A.) polymer dispersion and the silver screen cathode that has been previously oxidized in aqueous sodium iodide to create an adsorbate film of silver iodide is placed on top of the Nafion-covered side of the PEM. The entire assembly is then heated slowly to 130° C. and pressed together. The whole layered structure can be mounted in a cell that permits irradiation of the silver/silver iodide screen cathode.

A Spectra Physics Model 2020-05 argon ion laser, for example, can be used as a wavelength-selectable, directional light source for testing the photocatalytic response of the silver membrane cathode. The photocatalytic behavior of the silver/silver iodide screen can be confirmed in the potentiostatic mode of a Princeton Applied Research Model 263A potentiostat/galvanostat. The assembled fuel cell can be tested in galvanostat mode whereupon the current/potential behavior can be recorded as a function of laser wavelength and power, surface modification, and reactant gas pressure.

It will be appreciated that other embodiments of fuel cells can be constructed in accordance with the teachings herein. Other embodiments of the invention include one in which oxidation of the silver screen in an aqueous sodium iodide solution is performed so as to prevent oxidation at the ring where the screen electrode makes electrical contact with the cell walls that serve as the terminals for the cell. Prevention of oxidation of the silver at the electrical contact reduces cell resistance and can be easily accomplished by pressing onto the screen prior to oxidation a ring of inert plastic of width and diameter equal to that of the electrical contact ring of the cell support. The plastic ring is removed after oxidation of the uncovered silver to create a silver iodide adsorbate film. Underneath the plastic is unoxidized metallic silver that serves as the electrical contact of the cathode to the cell.

The light source of the invention can take on a variety of forms, including sunlight, arc and incandescent sources, and need not be a laser. In accordance with one embodiment, the light source can include a plurality of fiber optic cables adapted and configured to illuminate the cathode. Such application of fiber optic light distribution can be utilized to retain a traditional stacked configuration of sub cells, instead of the horizontal orientation discussed above. Also, a thin-film-transistor (TFT) display can also be employed. It will be understood that other types of lighting devices can be used, depending on the adsorbate material used. For example, if the energy difference between the electronic states of the metal-adsorbate composite is fairly small, lower energy light sources could be used, such as those operating in the infrared range. As such, in certain metal-adsorbate combinations, even a suitably configured radiative heating element could provide sufficient energy to drive the photocatalysis.

In certain circumstances, the silver cathode can be preroughened to affect photocatalytic behavior. The number of surface active sites is defined by the surface preparation. In this respect, the present inventor has discovered that, at a preroughened silver electrode, the active sites are confined to Ag+ sites at the surface which are the silver atoms at the apexes of surface bumps. Because the preroughened silver surface of the electrode is only fractionally covered by these bumps, the percentage of the surface that is active is rather limited.

In the present invention, it is believed that photocatalytic activity does not require preroughening of the silver surface. The photocatalytic activity arises instead from the band gap of the semiconductor which frustrates recombination of electrons and holes following excitation by light. It is believed therefore that the active sites of silver/silver iodide surface constitute nearly 100% of the entire surface. This feature offers overwhelming economic benefits compared to the existing fuel cells and electrodes in the art. Further, the utility of the silver/silver iodide cathode extends beyond its economic advantage, simplifying the fuel cell design in spite of the requirement for light at the cathode.

There are many other advantages that a photocatalytic fuel cell as described herein presents over a conventional fuel cell. As mentioned above, a platinum-catalyzed hydrogen fuel cell operates at moderate current levels at cell voltages close to +0.75 volts instead of the thermodynamic equilibrium cell voltage is +1.23 volts. This amounts to an overvoltage of −0.48 volts below the thermodynamic voltage, thus limiting the efficiency to near 60%. However, when electrodes as described herein are used in the place of a conventional cathode, there is virtually no tendency for the voltage of the metal to wander negatively, resulting in increased electrochemical efficiency of the cell, limited only by the oxidation potential of the metal used for the cathode. Platinum oxidizes at +1.18 Volts (vs. a normal hydrogen reference electrode: NHE). If gold is used as an electrode material, it is possible to operate the cell at the full voltage of 1.23 Volts, since gold oxidizes at about 1.498 volts vs. NHE. Silver oxidizes just negative of +0.80 Volts vs. NHE, near the same operating voltage of conventional Pt-containing fuel cells, but holds a significant economic advantage over platinum. Palladium oxidizes at +0.951 Volts vs. NHE and can be used as a catalyst.

It will be understood that while a PEM fuel cell has been illustrated above, electrodes made in accordance with the invention can be utilized with other types of fuel cells and hydrogen-containing fuels, including, for example, phosphoric acid fuel cells, solid oxide fuel cells, direct methanol fuel cells and the like.

### Electrodes

Another aspect of the invention provides an electrode comprising an electrically conductive material having an unroughened (or have not been pre-roughened) surface, where an adsorbate material is applied thereto. The adsorbate material used herein comprises a material having semiconductor properties, and the combination of the electrically conductive material and the adsorbate material is photosensitive and has catalytic properties.

In a specific embodiment, the electrode of the invention is a silver electrode, with a surface applied with an adsorbate material comprising silver iodide (referred to herein as silver/silver iodide electrode).

In certain embodiments, the electrode of the invention is used as a cathode in a fuel cell. In certain circumstances, when an electrode of the invention is used in a fuel cell, the voltage at the electrode (half-cell) is pH independent.

The electrically conductive material that may be used to make an electrode of the invention can be any material that contains movable electric charges. Examples of the electrically conductive material include, but are not limited to, metallic materials, graphite, and conductive polymers (such as, polyacetylene, polyphenylene vinylene, polypyrrole, polythiophene, polyaniline, and polyphenylene sulfide, and etc.).

In one embodiment, the electrode in accordance with the present invention is made from a metallic material. Such metallic materials that may be used include, but are not limited to, silver, osmium, palladium, iridium, platinum, gold, and alloys and mixtures thereof. In a specific embodiment, the electrode is made from silver.

It is further appreciated that an electrode made from silver or other conductive material that is plated with silver, such as a silver plated copper electrode, may be used as a silver electrode in accordance with the invention. It is believed that the electrode of the invention can also be carbon-based, which is coated with an electrically conductive material (e.g., a metallic material).

Other materials having a surface suitable for use as an electrode can also be employed to make the electrode (e.g., cathode) of the invention. Such materials are usually commercially available. For example, a porous, stainless steel screens of varying mesh are sold by Grainger Inc. Tel: 1-800-323-0620; www.grainger.com can be electroplated with silver and oxidized in an aqueous solution of sodium iodide to prepare a silver/silver iodide electrode with appropriate porosity toward gases and light.

### Adsorbate Materials

In accordance with the invention, any material that has semiconductor properties may be used as an adsorbate material of the invention. In certain embodiments, the material having semiconductor properties can be, for example, AgI, AgF, AgCl, AgBr, TiO₂, GaSe, InAs, InGaAs, ZnO, ZnS, ZnSe, HgZnTe, PbSe, PbS, PbSnTe, PtSi, HgI₂, TlBr, and mixtures thereof.

Certain embodiments of the invention provide that adsorbate material comprises a halogen-containing material. In a specific embodiment, the halogen-containing material is AgI.

In other embodiments, the adsorbate material comprises AgCl, AgBr, or TiO₂.

In certain embodiment, the adsorbate material of the invention becomes negatively charged upon irradiation with light. For example, the adsorbate material may become charged with iodide ions upon irradiation with light.

It is believed that the negatively charged adsorbate material becomes a source of reducing equivalents (electrons) for electroreduction of available substances like oxygen in a fuel cell. In a Ag/AgI electrode, it is believed that this behavior of the photoactivated Ag/AgI electrode becoming a source of electrons for electroreduction of oxygen eliminates the activation overvoltage, which is typical of oxygen reduction at platinum or other metal cathodes. This is one of the distinct advantages associated with the Ag/AgI photocathode, especially when compared to the traditional Pt/C electrode.

In certain circumstances, when incident photons interact with the adsorbate-covered metal surface, they inelastically scatter such that energy is either gained or lost by the photons. The scattered photons are shifted in frequency accordingly. This inelastic scattering is called Raman scattering.

One aspect of the invention provides that the electrode surface that is covered by an adsorbate material of the invention is unroughened (or has not been pre-roughened).

On the other hand, experiments have shown that electrochemical roughening, for example, can produce surface enhanced Raman scattering or SERS. For instance, when a silver electrode is used, the electrode surface may be roughened according to the following two-step procedure: a) immersing the silver electrode in a chloride medium followed by applying a positive voltage across the silver through the chloride medium, which causes silver to oxidize and form solid AgCl; and b) reversing the current to force reduction of the AgCl film, which cause the silver in solution to deposit back on the surface of the electrode. The re-deposition of silver normally leaves a roughened surface on the electrode, because the silver atoms do not go back where they came from and tend to pile up (see D. L. Jeanmaire, R. P. van Duyne, J. Electroanal. Chem. 84, 1-20 (1977) for a detailed description of the oxidation-reduction cycle).

Electrochemical roughening of gold in a chloride medium, for example, using a procedure similar to that discussed for silver above, has been demonstrated to yield the micro-roughened surface required for observation of SERS using gold, making gold suitable for use as an electrode as described herein. Ordinarily, oxidation of gold in chloride creates soluble gold chloride (AuCl₄⁻) unlike silver which forms an insoluble silver chloride (AgCl) precipitate at the surface. Dissolution of gold chloride during oxidation limits the roughness attainable during subsequent reduction of gold chloride and deposition of gold because the process is diffusion limited allowing time for migration of adatoms filling surface defects. To limit dissolution of the gold material and to form the microroughness required, multiple rapid oxidation-reduction cycles are performed. A detailed description of this process is known in the art and is described, for example, in Gao, Ping; Gosztola, David; Leung, Lam Wing H.; Weaver, Michael J. “Surface-enhanced Raman scattering at gold electrodes. Dependence on electrochemical pretreatment conditions and comparisons with silver”. Journal of Electroanalytical Chemistry and Interfacial Electrochemistry (1987), 233(1-2), 211-22.

In the present invention, however, the electrode surface is unroughened; that is, for example, the electrode surface is not prepared according to the above-described two-step pre-roughening procedure. For example, in a case when an silver/silver iodide electrode is involved, the AgI film is applied to the electrode surface by stepping the silver electrode voltage positively in an iodide medium until oxidation of the silver to silver iodide occurs. Once the silver iodide film is formed on the surface of the electrode, the preparation is considered completed and the electrode is removed from the iodide medium. In other words, the method does not comprise the reversing and re-depositing step of the roughening process, which involves depositing silver back onto the surface.

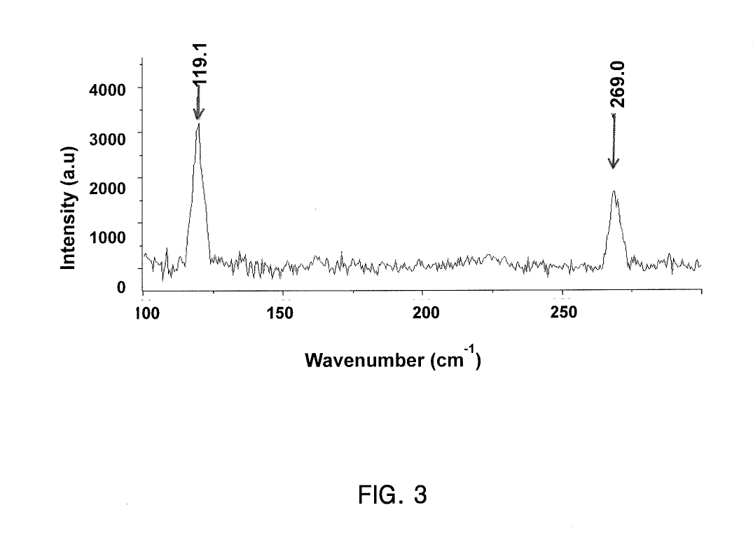

In accordance with one embodiment of the invention, the adsorbate material, when applied to an electrode surface, does not exhibit Raman scattering intensity that has been enhanced by the electrode surface. The adsorbate material at the unroughhened metal surface may nonetheless experience resonance enhancement of its Raman scattered light. Resonance Raman enhancement occurs when the energy of the incident light matches an energy gap in the adsorbate material or the metal-adsorbate composite. Such resonance Raman scattering is responsible for the observation by the present inventor of a Raman spectrum for AgI adsorbed at a silver electrode (FIG. 3) that reveals the presence of an I₂-like vibration at 119 cm⁻¹. The presence of I₂ supports the contention that the I₂/I-equilibrium defines the voltage at the Ag/AgI cathode.

### Methods of the Invention

The invention also provides a novel method for producing electricity. The method in accordance with the invention involves the use of a pH-dependent fuel cell comprising a cathode of the invention. Specifically, the method comprises steps, such as,

a) providing a cathode made from an electrically conductive material, wherein said cathode has a surface applied with an adsorbate material, said adsorbate material comprises a material having semiconductor properties, and said electrically conductive material and/or the adsorbate material are photosensitive and have catalytic properties;

b) operably coupling the cathode to a first portion of an electrolyte in the fuel cell;

c) operably coupling an anode to a second portion of the electrolyte; and

d) irradiating the cathode to cause an electrical current to flow across the cathode.

The method of the invention may further comprise a step of adjusting the pH value of the electrolyte.

In certain embodiments, the surface of the cathode employed herein is unroughened. And, the electrically conductive material to make the cathode is a metallic material selected from the group consisting of silver, osmium, palladium, iridium, platinum, gold, and alloys and mixtures thereof.

In one embodiment, the cathode used herein is a silver/silver iodide electrode.

In a case where a silver/silver iodide photocathode is used and when the anode reaction remains pH dependent, the fuel cell of the invention produces output voltage that increases by nearly 0.0591 volts with each unit increase in pH, as the cathodic reaction is constant over pH values. A detailed discussion of experiments performed on an aqueous photocatalytic fuel cell of the invention is provided in Example III below.

Another aspect of the invention provides a novel method of making an electrode. In accordance with one aspect, the electrode of the invention has a surface with an adsorbate material applied thereto. In certain embodiments, the method comprises:

a) providing an electrode made from an electrically conductive material;

b) polishing said electrode; and

c) applying the adsorbate material to the surface of the electrode, wherein said adsorbate material comprises a material having semiconductor properties, and said electrically conductive material and/or the adsorbate material are photosensitive and have catalytic properties;

wherein said electrode is not subjected to a roughening process of the surface thereof.

The adsorbate material may be applied by depositing adsorbate molecules onto an electrode surface, after immersing the electrode into a solution.

For example, silver iodide may be applied as the adsorbate material to a silver electrode through the following procedure: immersing the electrode in an aqueous solution of iodine (I₂) for a period of time. Iodine reacts with silver (Ag) to create a film of AgI.

In this case, the chemical reaction is

2Ag(s)+I₂(aq)->2AgI(s)

Alternatively, silver iodide may be applied through a procedure including steps of a) immersing the electrode to an aqueous solution containing iodide ions (such as, a NaI solution); and b) applying a positive voltage to the electrode for a period time such that a film of silver iodide forms on the surface of the electrode. Specifically, the voltage at the silver electrode immersed in the aqueous solution is moved positively until oxidation of silver to AgI occurs. The voltage is held at this positive voltage for a period of time to allow developing a film of AgI that grows with time.

### EXAMPLES

The present invention may be further illustrated by the following non-limiting examples describing the methods of the invention.

### Example I

### Photocatalytic Fuel Cell with Silver/Silver Iodide Cathode and Pt Anode

The Pt cathode in a traditional fuel cell was replaced with a photocatalytic silver/silver iodide electrode in accordance with the present invention. A leak-free silver/silver chloride electrode was used as a standard reference electrode. The open circuit voltage of each half-cell of the fuel cell was measured relative to the standard reference electrode.

It was found that the voltage of silver/silver iodide photocathode was consistently in the range 0.570-0.600 V at all pH values. This half-cell voltage closely corresponds to the standard reduction potential for iodine, I₂, 0.535 V, suggesting that the equilibrium at the photocathode of the invention was no longer the oxygen reduction reaction as in a traditional fuel cell. Without wishing to be bound by any theory, the inventor believes that the equilibrium at the silver/silver photocathode of the invention is

I₂(adsorbed)+2e−(aq)<=>2I-(adsorbed)E°=0.535 volts.

The presence of I₂ at the surface of the silver cathode was confirmed by surface Raman scattering, which showed the iodine-like vibration at 119 cm⁻¹ (FIG. 3).

Concomitantly, the Nernst equation for this equilibrium at the silver/silver iodide photocathode becomes

$${E}_{R} ( volts ) = {E}_{{I}_{2} / {I}^{-}}^{0} - \frac{RT}{2 F} ln \frac{{a}_{{I}^{-}}^{2}}{{a}_{{I}_{2 }}} = 0.535 V ,$$

assuming the activities of the adsorbed species are unity (1), and moves larger than 0.535 V when the activity of I— drops below unity.

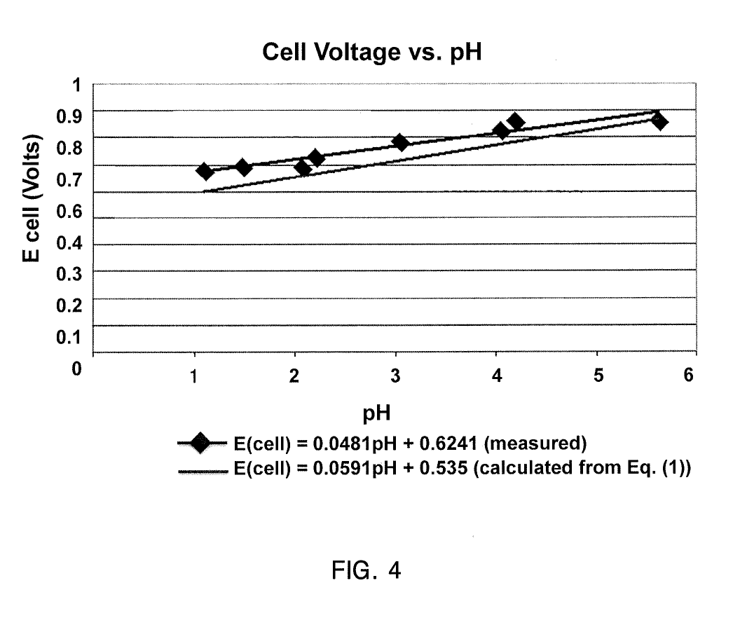

The resultant pH-dependent cell voltage (E_{cell}) is shown in FIG. 2 and measured in FIG. 4.

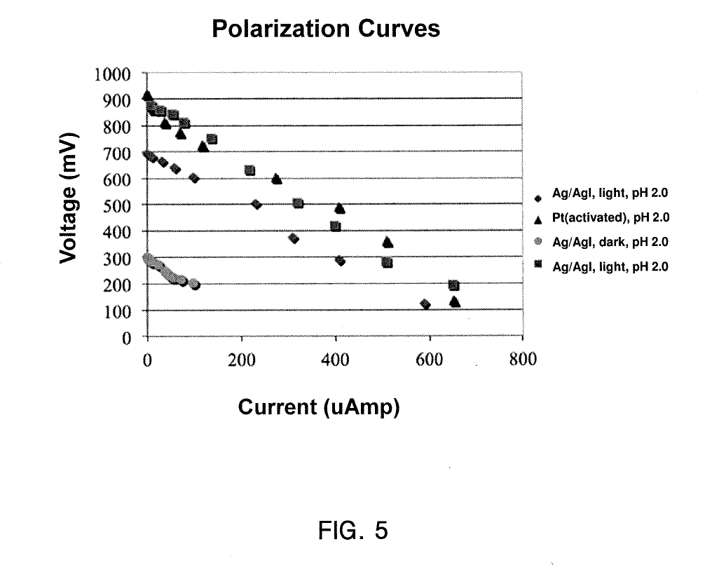

It was observed that that pH dependence of the open circuit voltage continued in the polarization curves with the power output of the Ag/AgI photocathode under irradiation at pH 8.0 improved over that at pH 2.0 and comparable to a platinum cathode (FIG. 5).

The data appears to support the above proposed model for I₂/I— controlling the equilibrium voltage of the photocathode. Activation polarization in the traditional fuel cell forces the cell voltage significantly below the thermodynamic expectation of 1.229 volts as indicated by the rapid drop in the current-voltage behavior at low current.

The fuel cell of the invention shows little activation polarization as can be seen from the absence of a sharp drop at low current levels (FIG. 5). It was hypothesized that photo-assisted electron transfer from the metal into the silver iodide adsorbate film leaves a negatively-polarized film that readily donates its excess electrons to oxygen largely eliminating the overvoltage.

### Example II

### Applying Silver Iodide Film to Silver Electrode

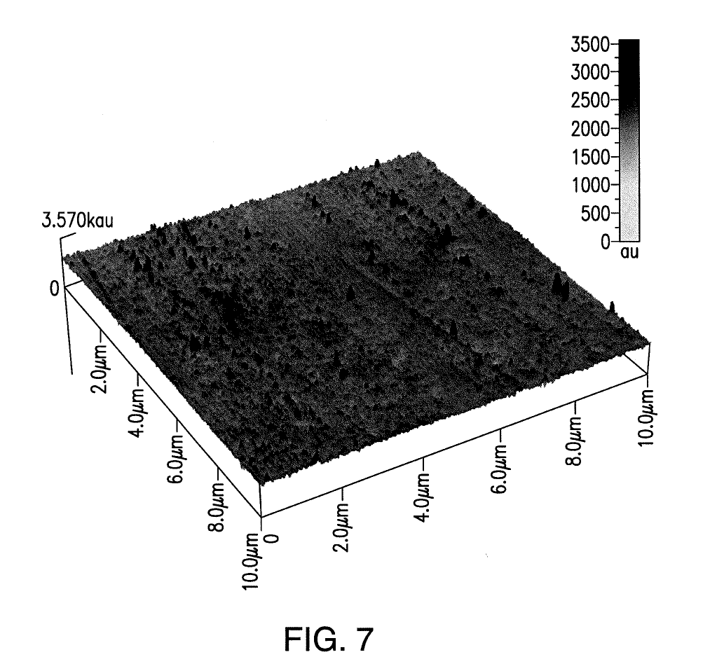

A silver electrode, freshly polished with progressively smaller aluminum oxide polishes to 0.03 micron (FIG. 7), was rinsed with distilled water and supported in an electrochemical cell containing a 0.1 M sodium chloride (NaCl) solution. The silver electrode serves as the working electrode whose voltage is adjusted relative to a silver/silver iodide (Ag/AgI) reference electrode. A platinum (Pt) counter electrode was added as the third electrode in the cell. The voltage of the cell was increased positively to +0.050 V relative to the Ag/AgI reference electrode.

At this voltage oxidation of the silver to silver iodide commences according to the equation:

Ag(s)+I-(aq)->AgI(s)+e−.

The oxidation continues until −100 millicoulombs per cm² surface area of charge passed, then the cell was removed from voltage control and the silver electrode removed from the cell and rinsed with distilled water.

The previously reflective silver electrode surface appeared yellowish gray, indicating the presence of the film of AgI. The silver iodide-coated silver electrode was then moved to the aqueous fuel cell for testing.

### Example III

### Measurement of Fuel Cell Voltage

An fuel cell containing an aqueous solution of 0.1 M sodium perchlorate with a silver/silver iodide photocathode and a platinum metal anode was constructed. The pH values of the electrolyte(s) were preset by small additions of perchloric acid or sodium hydroxide. The fuel cell was then irradiated. The output voltage of the fuel cell was measured.

Results are provides in Table 1:

TABLE 1

| | E_{cell} (volts), | E_{cell} (volts), calculated |
|---|---|---|
| pH | measured | from Eq. (1) |
| 1.1 | 0.679 | 0.600 |
| 2.07 | 0.691 | 0.657 |
| 2.206 | 0.730 | 0.665 |
| 5.62 | 0.863 | 0.867 |

The data of Table 1 supports the proposed model for I₂/I— controlling equilibrium voltage of the photocathode.

The measured equilibrium voltage at pH 5.86 (that is, 0.863 volts) is more positive than the typical operating voltage of 0.75 volts for a fuel cell under moderate power output. The output voltage of a normal cell when delivering power suffers from activation overvoltage, that is, the cell voltage drops significantly below the thermodynamic expectation of 1.229 volts. It was believed that the voltage loss is tied to the slow delivery of electrons to oxygen at electropositive metals including platinum. Only after lowering the voltage at the normal cathode (making the metal more negative) does significant current flow.

The fuel cell of the invention has demonstrated significant reduction in this activation overvoltage by effecting photo-assisted electron transfer from the metal into the silver iodide adsorbate film at the surface. The then negatively polarized film readily donates its excess electrons to oxygen largely eliminating the overvoltage requirement. Thus, it can be expected elimination of the activation polarization will yield minimal loss of the thermodynamic cell voltage upon current draw from the photocatalytic fuel cell of the invention. Other loss mechanisms such as ohmic loss would remain active. It further demonstrates that the pH dependent fuel cell of the invention as a promising alternative to those existing in the art.

### EQUIVALENTS

Those skilled in the art will recognize, or be able to ascertain using no more than routine experimentation, numerous equivalents to the specific procedures described herein. Such equivalents are considered to be within the scope of this invention and are covered by the following claims.

What is claimed is:

1. A fuel cell comprising,
(a) a membrane electrode assembly including:
i) an electrolyte;
i) an anode operably coupled to the electrolyte; and
ii) a cathode operably coupled to the electrolyte, wherein the cathode is made from an electrically conductive material, the cathode has a surface applied with an adsorbate material, and the adsorbate material comprises a material having semiconductor properties; wherein said surface of the cathode is unroughened, and said electrically conductive material and/or the adsorbate material are photosensitive and have catalytic properties; and
(b) a light source adapted and configured to irradiate the cathode to cause a steady flow of electrical current at the cathode.

2. The fuel cell of claim 1, wherein an output voltage of said fuel cell is pH dependent.

3. The fuel cell of claim 1, wherein said fuel cell is a hydrogen fuel cell.

4. The fuel cell of claim 1, wherein the electrically conductive material comprises a metallic material.

5. The fuel cell of claim 4, wherein the metallic material is selected from the group consisting of silver, osmium, palladium, iridium, platinum, gold, and alloys and mixtures thereof.

6. The fuel cell of claim 1, wherein said material having semiconductor properties is selected from the group consisting of AgI, AgF, AgCl, AgBr, TiO₂, GaSe, InAs, InGaAs, ZnO, ZnS, ZnSe, HgZnTe, PbSe, PbS, PbSnTe, PtSi, HgI₂, TlBr, and mixtures thereof.

7. The fuel cell of claim 1, wherein the adsorbate material comprises a halogen-containing material.

8. The fuel cell of claim 7, wherein the halogen-containing material is silver iodide.

9. The fuel cell of claim 1, wherein the cathode is a silver/silver iodide cathode.

10. An electrode, comprising an electrically conductive material having a surface applied with an adsorbate material, wherein said adsorbate material comprises a material having semiconductor properties, said surface of the cathode is unroughened, and said electrically conductive material and/or the adsorbate material are photosensitive and have catalytic properties.

11. The electrode of claim 10, wherein, when said electrode is used in a fuel cell, voltage at said electrode is pH independent.

12. The electrode of claim 10, wherein said electrically conductive material is a metallic material.

13. The electrode of claim 12, wherein said metallic material is selected from the group of silver, osmium, palladium, iridium, platinum, gold, and alloys and mixtures thereof.

14. The electrode of claim 12, wherein said metallic material is silver.

15. The electrode of claim 10, wherein said material having semiconductor properties is selected from the group consisting of AgI, AgF, AgCl, AgBr, TiO₂, GaSe, InAs, InGaAs, ZnO, ZnS, ZnSe, HgZnTe, PbSe, PbS, PbSnTe, PtSi, HgI₂, TlBr, and mixtures thereof.

16. The electrode of claim 10, wherein said adsorbate material comprises a halogen-containing material.

17. The electrode of claim 16, wherein said adsorbate material comprises AgI.

18. The electrode of claim 10, wherein said electrode is a silver/silver iodide electrode.

19. The electrode of claim 10, wherein said adsorbate material becomes negatively charged upon irradiation with light.

20. A method of making an electrode with an adsorbate material applied to a surface thereto, comprising:
a) providing an electrode made from an electrically conductive material;
b) polishing said electrode; and
c) applying the adsorbate material to the surface of the electrode, wherein said adsorbate material comprises a material having semiconductor properties, and said electrically conductive material and/or the adsorbate material are photosensitive and have catalytic properties;
wherein said electrode is not subjected to a roughening process of the surface thereof.

21. The method of claim 20, wherein the electrically conductive material is a metallic material selected from the group of silver, osmium, palladium, iridium, platinum, gold, and alloys and mixtures thereof.

22. The method of claim 21, wherein said metallic material is silver.

23. The method of claim 22, wherein the step of applying the adsorbate material to the surface of the electrode is carried out by immersing the electrode to a solution containing iodine.

24. The method of claim 23, wherein the electrode is immersed into the solution for a period of time such that a film of silver iodide develops on the surface of the electrode.

25. The method of claim 22, wherein the step of applying the adsorbate material to the surface of the electrode is carried out by immersing the electrode to an aqueous solution of sodium iodide (NaI).

26. The method of claim 25, wherein a positive voltage is applied to the electrode immersed in the aqueous solution for a period time such that a film of silver iodide forms on the surface of the electrode.

27. A method of producing electricity through a pH-dependent fuel cell, comprising
a) providing a cathode made from an electrically conductive material, wherein said cathode has a surface applied with an adsorbate material, said adsorbate material comprises a material having semiconductor properties, and said electrically conductive material and/or the adsorbate material are photosensitive and have catalytic properties;
b) operably coupling the cathode to a first portion of an electrolyte in the fuel cell;
c) operably coupling an anode to a second portion of the electrolyte; and
d) irradiating the cathode to cause an electrical current to flow across the cathode.

28. The method of claim 27, wherein said surface of the cathode is unroughened.

29. The method of claim 27, wherein said method further comprises a step of adjusting the pH value of the electrolyte.

30. The method of claim 27, wherein said electrically conductive material is a metallic material selected from the group consisting of silver, osmium, palladium, iridium, platinum, gold, and alloys and mixtures thereof.

31. The method of claim 27, wherein said material having semiconductor properties is selected from the group consisting of AgI, AgF, AgCl, AgBr, TiO₂, GaSe, InAs, InGaAs, ZnO, ZnS, ZnSe, HgZnTe, PbSe, PbS, PbSnTe, PtSi, HgI₂, TlBr, and mixtures thereof.

32. The method of claim 27, wherein the cathode is made from silver, and the adsorbate material comprises AgI.
